(19) United States
(12) Patent Application Publication
(10) Pub. No.: US 2018/0024662 A1
(43) Pub. Date: Jan. 25, 2018

(54) TOUCH DISPLAY SCREEN AND METHOD FOR FORMING THE SAME

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Min HE, Beijing (CN); Jing WANG, Beijing (CN); Xiaodong XIE, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/650,154

(22) Filed: Jul. 14, 2017

(30) Foreign Application Priority Data
Jul. 20, 2016 (CN) 201610576099.9

(51) Int. Cl. G06F 3/041; C09J 5/06; C09J 5/04; G02F 1/1333; H01L 27/32

(52) U.S. Cl. CPC G06F 3/041; G02F 1/13338; H01L 27/323; C09J 5/04; C09J 5/06; G06F 2203/04103; G06F 3/044

(57) ABSTRACT

A touch display screen and a method for forming the same are provided, which are related to the touch technology. The touch display screen includes a touch screen, a display screen and a buffer layer. The buffer layer is on lateral surfaces of the touch screen and encircles the touch screen.

### CROSS-REFERENCE TO RELATED APPLICATION

This application claims a priority to Chinese Patent Application No. 201610576099.9 filed on Jul. 20, 2016, the disclosures of which are incorporated in their entirety by reference herein.

### TECHNICAL FIELD

The present disclosure relates to the field of touch technology, and in particular to a touch display screen and a method for forming the same.

### BACKGROUND

Along with the development of display technology, the touch display technology has entered into a period of rapid development, which is widely applied to cell phone and tablet PC, even to the laptop, display and television.

A touch screen of a touch product is required to have sufficient strength, especially for the cell phone and tablet product. It is proved in the experiment that, cracks of the touch screen of the touch product occurs from an edge portion of a glass, the strength of the edge portion of the touch screen is very important for the strength of the entire touch screen.

In the related art, a high-strength glass is used as a base material to meet the strength requirement of the touch product. However, along with a popularization of the touch display screen technology, a technical threshold thereof is decreased continuously, while a competition is becoming fiercer, and then the manufacturers may guarantee a profit by reducing the cost, therefore it is impossible to apply the costly high-strength glass to the low-cost touch product.

### SUMMARY

The present disclosure provides in at least one embodiment a touch display screen and a method for forming the same, so as to improve an overall strength of the touch display screen with a lower cost.

To achieve the above objective, in one aspect, a touch display screen is provided in the present disclosure, including a touch screen, a display screen and a buffer layer. The buffer layer is on lateral surfaces of the touch screen and encircles the touch screen.

Optionally, a thickness of the buffer layer is about 10 μm to 100 μm.

Optionally, the touch screen and the display screen are adhered to each other through an adhesive layer, and a material of the buffer layer is identical to the adhesive layer.

Optionally, the material of the buffer layer and the adhesive layer is an optical clear resin (OCR).

Optionally, the display screen is a liquid crystal display (LCD) screen or an organic light-emitting diode (OLED) display screen.

Optionally, the touch screen includes a glass substrate and a touch structure, and the glass substrate is provided with an upper surface, a lower surface and a plurality of lateral surfaces, the touch structure is on the upper surface of the glass substrate, and the buffer layer is on the lateral surfaces.

Optionally, the glass substrate is embraced by the buffer layer having a hollow-square shape.

Optionally, the buffer layer includes a plurality of portions, each portion of the buffer layer corresponds to one lateral surface of the glass substrate, and respective portions of the buffer layer extend by an identical distance along a direction perpendicular to a corresponding lateral surface of the glass substrate.

Optionally, the distance is about 10 μm to 100 μm.

Optionally, the touch display screen further includes an adhesive layer between the touch structure and the display screen and configured to adhere the touch screen to the display screen.

Optionally, the buffer layer is provided with an upper surface and a lower surface, the upper surface of the buffer layer is at a plane identical to the upper surface of the glass substrate, and the lower surface of the buffer layer is at a plane identical to the lower surface of the glass substrate.

Optionally, the buffer layer is made of a resin material.

In another aspect, a method for forming a touch display screen is further provided in the present disclosure, including: forming on lateral surfaces of a touch screen a buffer layer encircling the touch screen; forming an adhesive layer on an adhesion surface of the touch screen; and arranging an adhesion surface of the display screen opposite to the adhesion surface of the touch screen and adhering the display screen to the touch screen, to form the touch display screen.

Optionally, the forming on the lateral surfaces of the touch screen the buffer layer encircling the touch screen includes forming the buffer layer of a thickness about 10 μm to 100 μm.

Optionally, the method further includes: forming a protective film on a touch surface of the touch screen; putting the touch screen having the protective film into an adhesion kit to enable the protective film to be in contact with a bottom of the adhesion kit, where there exists an interval between the touch screen and a side wall of the adhesion kit; injecting a glue into the interval between the touch screen and the adhesion kit, and coating the glue onto a region of the adhesion surface of the touch screen corresponding to the display screen; arranging the adhesion surface of the display screen opposite to the adhesion surface of the touch screen and adhering the display screen to the touch screen, and putting the adhesion kit into a stove to solidify the glue, to form the buffer layer by the glue between the touch screen and the adhesion kit and form the adhesive layer by the glue between the touch screen and the display screen; and removing the adhesion kit and peeling off the protective film.

Optionally, the injecting the glue into the interval between the touch screen and the adhesion kit includes injecting the glue made of an optical clear resin (OCR) into the interval between the touch screen and the adhesion kit.

Optionally, prior to the putting the touch screen having the protective film into the adhesion kit, the method further includes: coating a release agent onto an inner surface of the side wall of the adhesion kit.

Optionally, the touch display screen includes the touch screen, the display screen and a buffer layer, the touch screen includes a glass substrate and a touch structure, and the glass substrate is provided with an upper surface, a lower surface and a plurality of lateral surfaces, where the method includes: forming the buffer layer on the lateral surfaces of the glass substrate; forming the adhesion layer on a surface of the touch structure away from the glass substrate; and arranging the adhesion surface of the display screen opposite to the surface of the touch structure away from the glass substrate and adhering the display screen to the touch structure, to form the touch display screen.

Optionally, prior to the forming the buffer layer on the lateral surfaces of the glass substrate, the method further includes: forming a protective film on the lower surface of the glass substrate; putting the touch screen having the protective film into an adhesion kit, to enable the protective film to be in contact with a bottom of the adhesion kit, and to enable intervals between respective lateral surfaces of the glass substrate and a corresponding portion of the side wall of the adhesion kit to be of an identical width; the width is a distance between each lateral surface of the glass substrate and a corresponding portion of the side wall of the adhesion kit.

Optionally, the forming the buffer layer on the lateral surfaces of the glass substrate includes: injecting a glue into the interval between the adhesion kit and the glass substrate, to form the buffer layer.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1(a) is a sectional view of a touch display screen in at least one embodiment of the present disclosure;

FIG. 1(b) is a top view of a touch screen in at least one embodiment of the present disclosure;

FIG. 2(a) is a schematic view of a touch structure in at least one embodiment of the present disclosure;

FIG. 2(b) is a schematic view of a touch structure in at least one embodiment of the present disclosure;

FIG. 2(c) is a schematic view of a touch structure in at least one embodiment of the present disclosure;

FIG. 3 is a schematic view of a display screen in at least one embodiment of the present disclosure;

FIG. 4 is a schematic view of a display screen in at least one embodiment of the present disclosure;

FIG. 5 is a flow chart of a method for forming a touch display screen in at least one embodiment of the present disclosure;

FIGS. 6(a)-6(d) show a flow of a method for forming a touch display screen in at least one embodiment of the present disclosure; and

FIGS. 7(a)-7(d) show a flow of a method for forming a touch display screen in at least one embodiment of the present disclosure.

### DETAILED DESCRIPTION

The present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

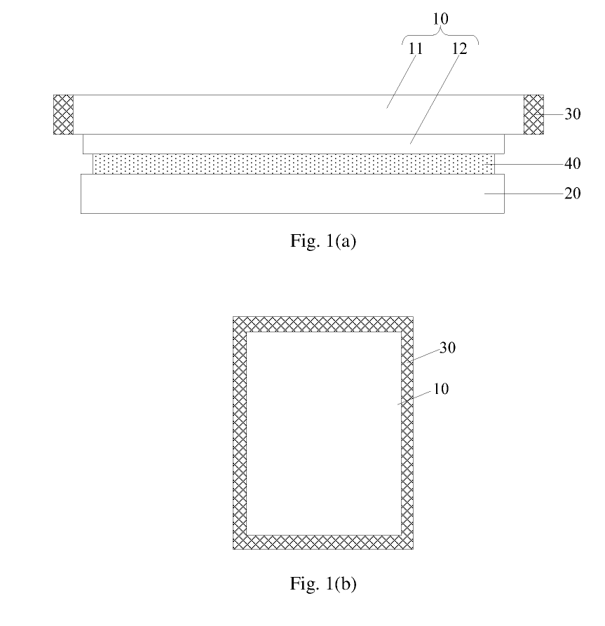

The present disclosure provides in at least one embodiment a touch display screen. As shown in FIG. 1(a) and FIG. 1(b), the touch display screen includes a touch screen 10, a display screen 20 and a buffer layer 30 on lateral surfaces of the touch screen and encircling the touch screen 10. The touch screen includes a glass substrate 11 and a touch structure 12 arranged on the glass substrate 11. The glass substrate 11 is provided with an upper surface, a lower surface and a plurality of lateral surfaces. The touch structure 12 is on the upper surface of the glass substrate 11, and the buffer layer 30 is on the lateral surfaces of the glass substrate 11, and the glass substrate 11 is embraced by the buffer layer 30 having a hollow-square shape.

As shown in FIG. 1(a), the buffer layer 30 includes a plurality of portions, each portion of the buffer layer 30 corresponds to one lateral surface of the glass substrate 11, and respective portions of the buffer layer 30 extend by an identical distance along a direction perpendicular to a corresponding lateral surface of the glass substrate 11.

In at least one embodiment of the present disclosure, the extension distance is about 10 μm to 100 μm.

In at least one embodiment of the present disclosure, as shown in FIG. 1(a), the touch display screen further includes an adhesive layer 40 between the touch structure and the display screen 20 and configured to adhere the touch screen 10 to the display screen 20.

In at least one embodiment of the present disclosure, as shown in FIG. 1(a), the buffer layer 30 is provided with an upper surface and a lower surface, the upper surface of the buffer layer 30 is at a plane identical to the upper surface of the glass substrate 11, and the lower surface of the buffer layer 30 is at a plane identical to the lower surface of the glass substrate 11.

The touch structure 12 may be a self-capacitive touch structure or a mutual-capacitive touch structure.

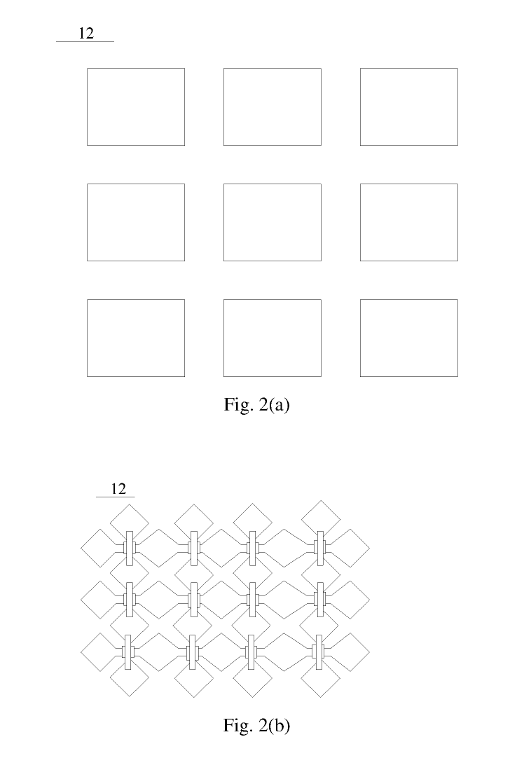

For a self-capacitive touch structure 12, as shown in FIG. 2(a), the touch structure 12 includes a plurality of rectangular touch electrodes. For a self-capacitive touch structure 12, as shown in FIG. 2(b) or 2(c), the touch structure 12 includes touch sensing electrodes and touch drive electrodes which are cross to each other.

The display screen 20 may be a liquid crystal display (LCD) screen, an organic light emitting diode (OLED) display screen or an electrophoretic display screen.

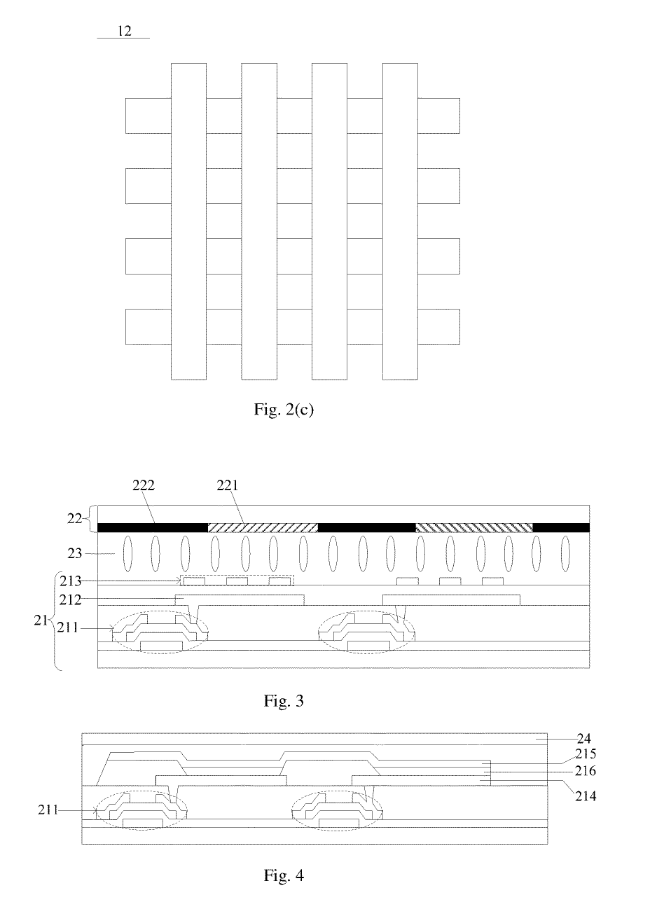

To be specific, in the case that the display screen 20 is a LCD screen, as shown in FIG. 3, the touch display screen includes an array substrate 21, an opposite substrate 22 and a liquid crystal layer 23 therebetween.

The array substrate 21 includes thin film transistors (TFT) 211 on a base substrate and pixel electrodes 212 electrically connected to drain electrodes of the TFTs 211. The array substrate 21 may further include common electrodes 213. Based on this, the pixel electrodes 212 and the common electrodes 213 may be arranged at different layers, as shown in FIG. 3, the upper electrodes are strip-like, and the lower electrodes are bar-like. Of course, the pixel electrodes 212 and the common electrodes 213 may be arranged at an identical layer, the pixel electrodes 212 are space apart from the common electrodes 213, and the pixel electrodes 212 and the common electrodes 213 are both strip-like electrodes.

The TFT 211 may be an A-Si TFT, P-Si TFT, metallic oxide TFT, organic TFT, etc. The TFT 211 may be a bottom-gate TFT or a top-gate TFT.

The opposite substrate 22 may include a color filter film 221 and a black matrix 222.

Of course, the color filter film 221 may be arranged on the array substrate 21, and the common electrodes 213 may be arranged on the opposite substrate 22.

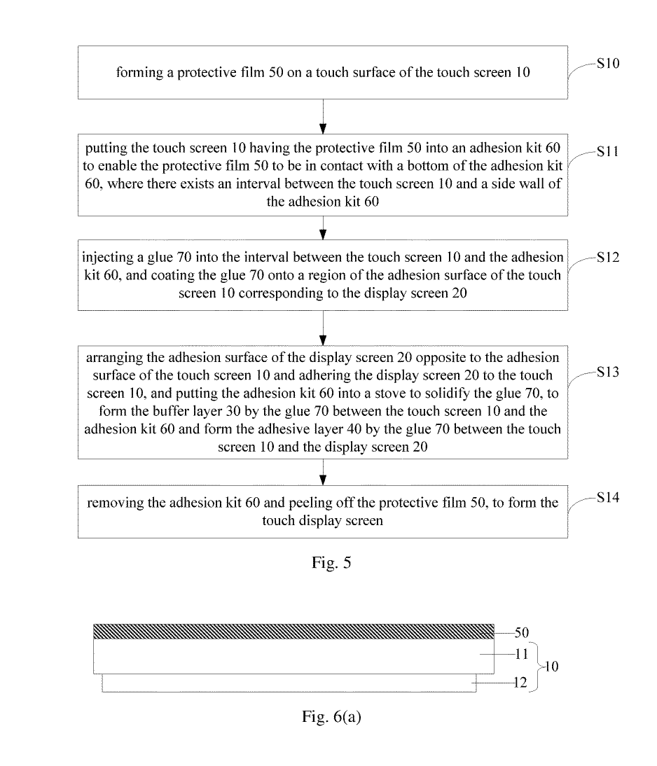

In the case that the display screen 20 is an OLED display screen, as shown in FIG. 4, the touch display screen includes a TFT 211 arranged on a base substrate, an anode electrode 214 electrically connected to a drain electrode of the TFT, a cathode electrode 215, an organic functional layer 216 and an encapsulation cover plate 24.

The organic functional layer 216 at least includes an electron transmission layer, a light-emitting layer and a hole transmission layer. In order to improve an efficiency of injecting electrons and holes into the light-emitting layer, the organic functional layer 216 may further include an electron injection layer between the cathode and the electron transmission layer and a hole injection layer between the anode and the hole transmission layer.

It should be noted that, firstly, the touch screen 10 is adhered to the display screen 20 through an adhesive layer 40. The adhesive layer 40 may be made of a material by which the touch screen 10 may be adhered to the display screen 20 and a transmittance of light beams transmitted from the display screen 20 may not be adversely affected.

Secondly, the buffer layer 30 may be arranged on lateral surfaces of the glass substrate 11 and encircle the glass substrate 11. The glass substrate 11 includes an upper surface where the touch structure 12 is arranged, a lower surface away from the upper surface and the lateral surfaces between the upper surface and the lower surface. The buffer layer 30 is arranged on the lateral surfaces of the glass substrate 11 excepting the upper surface and the lower surface of the glass substrate 11.

Thirdly, the material of the buffer layer 30 is not limited, as long as an impact force applied to the edge portion of the touch screen 10 may be released.

In view of the cost, in at least one embodiment of the present disclosure, the buffer layer 30 is made of resin.

Based on this, the glass substrate 11 may be made of an ordinary glass instead of an expensive high-strength glass.

According to the touch display screen in at least one embodiment of the present disclosure, by arranging the buffer layer 30 which is arranged on the lateral surfaces of the touch screen 10 and encircles the touch screen 10, the buffer layer 30 may function as a pad when the touch screen 10 is impacted, so as to release the impact force applied to the touch screen 10, thereby improving the strength of the edge portion of the touch screen 10 and the overall strength of the touch display screen 10. Based on this, compared with the related art applying the expensive high-strength glass, the buffer layer 30 may be made of a small amount of ordinary material, thereby reducing the cost.

Optionally, the buffer layer 30 is of an identical thickness.

Optionally, the thickness of the buffer layer 30 is about 10 μm to 100 μm.

The thickness of the buffer layer 30 refers to a thickness of the buffer layer 30 along a direction perpendicular to the lateral surface of the glass substrate 11.

On one hand, the buffer layer 30 may be thin enough to be assembled with the housing in the subsequent process, therefore the buffer layer 30 may be compatible with the housing in the related art. On the other hand, the buffer layer 30 may be thick enough to release the impact force applied to the touch screen 10.

Based on the above description, the manufacturing process of the touch display screen includes: forming the adhesive layer 40 on the adhesion surface of the touch screen 10 (i.e., a side of the glass substrate 11 where the touch structure is arranged), and then an adhesion surface of the display screen 20 (i.e., the light-emitting surface) is adhered to the adhesion surface of the touch screen 10, so as to form the touch display screen. Based on this, by providing a corresponding adhesion kit, the buffer layer 30 may be formed on the lateral surfaces of the touch screen 10 and encircle the touch screen 10 while forming the adhesive layer 40.

In at least one embodiment of the present disclosure, the buffer layer 30 may be made of a material identical to the adhesive layer 40, thereby simplifying the process and further reducing the cost.

Furthermore, because the optical clear resin (OCR) has a good stickiness and a high transmittance and has little effect on the display, in at least one embodiment of the present disclosure, the buffer layer 30 and the adhesive layer 40 are both made of OCR.

The present disclosure further provides in at least one embodiment a method for forming a touch display screen. As shown in FIG. 1, the method includes: forming on lateral surfaces of the touch screen 10 a buffer layer 30 encircling the touch screen 10; forming the adhesive layer 40 on an adhesion surface of the touch screen 10; and arranging an adhesion surface of the display screen 20 opposite to the adhesion surface of the touch screen 10 and adhering the display screen 20 to the touch screen 10, to form the touch display screen.

According to the method for forming the touch display screen in at least one embodiment of the present disclosure, by arranging the buffer layer 30 which is arranged on the lateral surfaces of the touch screen 10 and encircles the touch screen 10, the buffer layer 30 may function as a pad when the touch screen 10 is impacted, so as to release the impact force applied to the touch screen 10, thereby improving the strength of the edge portion of the touch screen 10 and the overall strength of the touch display screen. Based on this, compared with the related art applying the expensive high-strength glass, the buffer layer 30 may be made of a small amount of ordinary material, thereby reducing the cost.

Optionally, the thickness of the buffer layer 30 is about 10 μm to 100 μm.

On one hand, the buffer layer 30 may be thin enough to be assembled with the housing in the subsequent process, therefore the buffer layer 30 may be compatible with the housing in the related art. On the other hand, the buffer layer 30 may be thick enough to release the impact force applied to the touch screen 10.

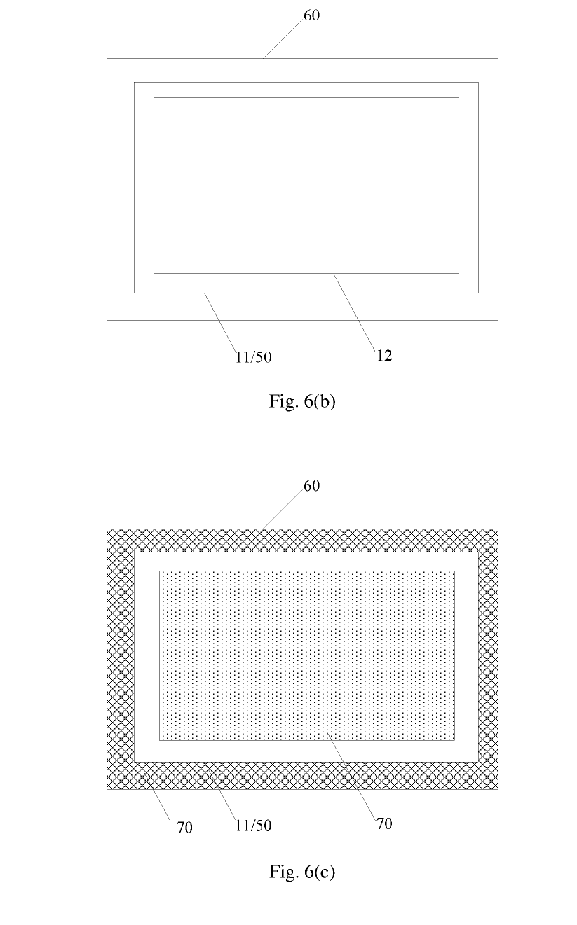

As shown in FIG. 5, the method for forming the touch display screen includes the following steps.

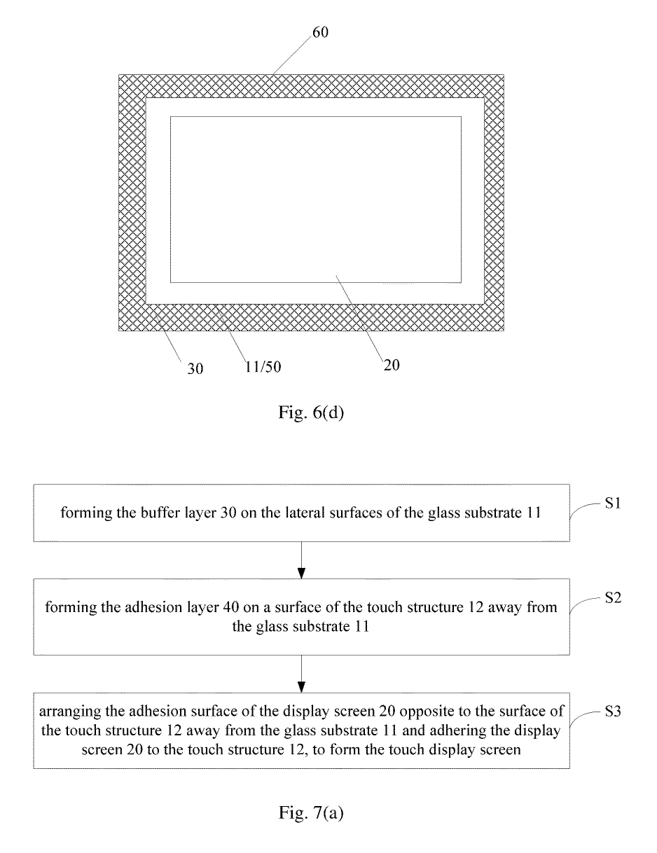

S10: forming a protective film 50 on a touch surface of the touch screen 10, as shown in FIG. 6(a).

The touch surface of the touch screen 10 refers to a surface of the glass substrate 11 of the touch screen 10 away from the touch structure 12.

The protective film 50 may be made of an organic material. The protective film 50 is configured to prevent the glue from adhering to the glass substrate 11 and making the touch surface of the touch screen 10 irregular as a result.

S11: putting the touch screen 10 having the protective film 50 into an adhesion kit 60 to enable the protective film 50 to be in contact with a bottom of the adhesion kit 60, where there exists an interval between the touch screen 10 and a side wall of the adhesion kit 60, as shown in FIG. 6(b).

S12: injecting a glue 70 into the interval between the touch screen 10 and the adhesion kit 60, and coating the glue 70 onto a region of the adhesion surface of the touch screen 10 corresponding to the display screen 20, as shown in FIG. 6(c).

The adhesion kit 60 and the glass substrate 11 may be of an identical shape, and a width of the interval between the adhesion kit 60 and the touch screen 10 may be determined based on the thickness of the buffer layer 30.

S13: arranging the adhesion surface of the display screen 20 opposite to the adhesion surface of the touch screen 10 and adhering the display screen 20 to the touch screen 10, and putting the adhesion kit 60 into a stove to solidify the glue 70, to form the buffer layer 30 by the glue 70 between the touch screen 10 and the adhesion kit 60 and form the adhesive layer 40 by the glue 70 between the touch screen 10 and the display screen 20, as shown in FIG. 6(d).

A temperature within the stove may be from 150° C. to 200° C.

S14: removing the adhesion kit 60 and peeling off the protective film 50, to form the touch display screen as shown in FIG. 1.

In order not to remove the buffer layer 30 while removing the adhesion kit 60, optionally, prior to S11, the method further includes coating a release agent onto an inner surface of the side wall of the adhesion kit 60.

Of course, the adhesion kit 60 may be made of a material not prone to be adhered to the buffer layer 30.

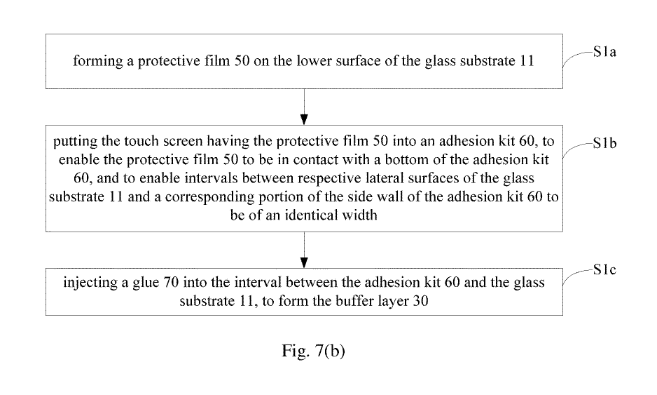

In at least one embodiment of the present disclosure, the touch display screen includes the touch screen 10, the display screen 20 and a buffer layer 30, the touch screen 10 includes a glass substrate 11 and a touch structure 12, and glass substrate 11 is provided with an upper surface, a lower surface and a plurality of lateral surfaces. As shown in FIG. 7(a), the method includes the following steps.

S1: forming the buffer layer 30 on the lateral surfaces of the glass substrate 11;

S2: forming the adhesion layer 40 on a surface of the touch structure 12 away from the glass substrate 11; and

S3: arranging the adhesion surface of the display screen 20 opposite to the surface of the touch structure 12 away from the glass substrate 11 and adhering the display screen 20 to the touch structure 12, to form the touch display screen.

In at least one embodiment of the present disclosure, prior to the forming the buffer layer 30 on the lateral surfaces of the glass substrate 11, the method further includes the following steps.

S1a: forming a protective film 50 on the lower surface of the glass substrate 11;

S1b: putting the touch screen having the protective film 50 into an adhesion kit 60, to enable the protective film 50 to be in contact with a bottom of the adhesion kit 60, and to enable intervals between respective lateral surfaces of the glass substrate 11 and a corresponding portion of the side wall of the adhesion kit 60 to be of an identical width.

The width is a distance between each lateral surface of the glass substrate 11 and a corresponding portion of the side wall of the adhesion kit 60.

In at least one embodiment of the present disclosure, as shown in FIG. 7(b), the forming the buffer layer 30 on the lateral surfaces of the glass substrate 11 includes:

S1c: injecting a glue 70 into the interval between the adhesion kit 60 and the glass substrate 11, to form the buffer layer 30.

Based on the above description, because OCR has a good stickiness and a high transmittance and has little effect on the display, in at least one embodiment of the present disclosure, the glue 70 is made of OCR.

The above are merely the preferred embodiments of the present disclosure. Obviously, a person skilled in the art may make further modifications and improvements without departing from the spirit of the present disclosure, and these modifications and improvements shall also fall within the scope of the present disclosure.

What is claimed is:

1. A touch display screen, comprising a touch screen, a display screen and a buffer layer, wherein the buffer layer is on lateral surfaces of the touch screen and encircles the touch screen.

2. The touch display screen according to claim 1, wherein a thickness of the buffer layer is about 10 μm to 100 μm.

3. The touch display screen according to claim 1, wherein the touch screen and the display screen are adhered to each other through an adhesive layer; and
a material of the buffer layer is identical to the adhesive layer.

4. The touch display screen according to claim 3, wherein the material of the buffer layer and the adhesive layer is an optical clear resin (OCR).

5. The touch display screen according to claim 1, wherein the display screen is a liquid crystal display (LCD) screen or an organic light-emitting diode (OLED) display screen.

6. The touch display screen according to claim 1, wherein the touch screen comprises a glass substrate and a touch structure, and the glass substrate is provided with an upper surface, a lower surface and a plurality of lateral surfaces;
the touch structure is on the upper surface of the glass substrate; and
the buffer layer is on the lateral surfaces.

7. The touch display screen according to claim 6, wherein the glass substrate is embraced by the buffer layer having a hollow-square shape.

8. The touch display screen according to claim 6, wherein the buffer layer comprises a plurality of portions, each portion of the buffer layer corresponds to one lateral surface of the glass substrate, and respective portions of the buffer layer extend by an identical distance along a direction perpendicular to a corresponding lateral surface of the glass substrate.

9. The touch display screen according to claim 8, wherein the distance is about 10 μm to 100 μm.

10. The touch display screen according to claim 6, further comprising an adhesive layer between the touch structure and the display screen and configured to adhere the touch screen to the display screen.

11. The touch display screen according to claim 6, wherein the buffer layer is provided with an upper surface and a lower surface, the upper surface of the buffer layer is at a plane identical to the upper surface of the glass substrate, and the lower surface of the buffer layer is at a plane identical to the lower surface of the glass substrate.

12. The touch display screen according to claim 6, wherein the buffer layer is made of a resin material.

13. A method for forming a touch display screen, comprising:
forming on lateral surfaces of a touch screen a buffer layer encircling the touch screen;
forming an adhesive layer on an adhesion surface of the touch screen; and
arranging an adhesion surface of the display screen opposite to the adhesion surface of the touch screen and adhering the display screen to the touch screen, to form the touch display screen.

14. The method according to claim 13, wherein the forming on the lateral surfaces of the touch screen the buffer layer encircling the touch screen comprises forming the buffer layer of a thickness about 10 μm to 100 μm.

15. The method according to claim 13, further comprising:
forming a protective film on a touch surface of the touch screen;
putting the touch screen having the protective film into an adhesion kit to enable the protective film to be in contact with a bottom of the adhesion kit, wherein there exists an interval between the touch screen and a side wall of the adhesion kit;
injecting a glue into the interval between the touch screen and the adhesion kit, and coating the glue onto a region of the adhesion surface of the touch screen corresponding to the display screen;
arranging the adhesion surface of the display screen opposite to the adhesion surface of the touch screen and adhering the display screen to the touch screen, and putting the adhesion kit into a stove to solidify the glue, to form the buffer layer by the glue between the touch screen and the adhesion kit and form the adhesive layer by the glue between the touch screen and the display screen; and
removing the adhesion kit and peeling off the protective film.

16. The method according to claim 15, wherein the injecting the glue into the interval between the touch screen and the adhesion kit comprises injecting the glue made of an optical clear resin (OCR) into the interval between the touch screen and the adhesion kit.

17. The method according to claim 15, wherein prior to the putting the touch screen having the protective film into the adhesion kit, the method further comprises:
coating a release agent onto an inner surface of the side wall of the adhesion kit.

18. The method according to claim 13, wherein the touch display screen comprises the touch screen, the display screen and a buffer layer,
the touch screen comprises a glass substrate and a touch structure, and the glass substrate is provided with an upper surface, a lower surface and a plurality of lateral surfaces, wherein the method comprises:
forming the buffer layer on the lateral surfaces of the glass substrate;
forming the adhesion layer on a surface of the touch structure away from the glass substrate; and
arranging the adhesion surface of the display screen opposite to the surface of the touch structure away from the glass substrate and adhering the display screen to the touch structure, to form the touch display screen.

19. The method according to claim 18, wherein prior to the forming the buffer layer on the lateral surfaces of the glass substrate, the method further comprises:
forming a protective film on the lower surface of the glass substrate; and
putting the touch screen having the protective film into an adhesion kit, to enable the protective film to be in contact with a bottom of the adhesion kit, and to enable intervals between respective lateral surfaces of the glass substrate and a corresponding portion of the side wall of the adhesion kit to be of an identical width,
wherein the width is a distance between each lateral surface of the glass substrate and a corresponding portion of the side wall of the adhesion kit.

20. The method according to claim 19, wherein the forming the buffer layer on the lateral surfaces of the glass substrate comprises: injecting a glue into the interval between the adhesion kit and the glass substrate, to form the buffer layer.
